(19) United States
(12) Patent Application Publication
(10) Pub. No.: US 2023/0116440 A1
(43) Pub. Date: Apr. 13, 2023

(54) TOP VIA STRUCTURE MADE WITH BI-LAYER TEMPLATE

(71) Applicant: International Business Machines Corporation, Armonk, NY (US)

(72) Inventors: Koichi Motoyama, Clifton Park, NY (US); CHANRO PARK, Clifton Park, NY (US); Kenneth Chun Kuen Cheng, Shatin (HK); Chih-Chao Yang, Glenmont, NY (US)

(21) Appl. No.: 17/498,718

(22) Filed: Oct. 11, 2021

(51) Int. Cl. H01L 23/532; H01L 23/522; H01L 21/768; H01L 21/304

(52) U.S. Cl. CPC H01L 23/53266; H01L 23/53238; H01L 23/5226; H01L 21/7688; H01L 21/76832; H01L 21/7684; H01L 21/304

(57) ABSTRACT

An exemplary semiconductor structure includes a substrate defining a first trench; a first refractory metal liner coating the first trench; a heavy metal liner coating the first refractory metal liner; a copper structure filling the first trench over the heavy metal liner; a generally planar capping dielectric layer on top of the substrate and the copper structure; a low-k dielectric layer on top of the capping dielectric layer, wherein the low-k dielectric layer defines a second trench; a second refractory metal liner coating the second trench; a metal line filling the second refractory metal liner; and a metal via protruding from the metal line.

### BACKGROUND

The present invention relates to the electrical, electronic, and computer arts, and more specifically, to sub-10 nanometer process nodes.

As semiconductor fabrication continues a trend toward smaller process dimensions, structural imperfections are becoming increasingly important in the performance of semiconductor products. Materials begin to be selected not for their bulk properties, but rather for their tolerance of imperfections at nanometer and angstrom scales. A salient example is the burgeoning use of “alternative metals” in semiconductor circuit designs. Although copper (Cu) has long been the favorite for integrated circuits, due to its very high bulk conductivity and lower cost than silver, imperfect line or via profiles at the smaller modern process dimensions can introduce electron scattering effects that detract from conductivity at the nanoscale.

Conductivity losses due to electron scattering are driven by structural variations or imperfections (roughness) on the order of or smaller than the mean free path length of the conductive material. Alternative metals, such as ruthenium (Ru), cobalt (Co), vanadium (Va), iridium (Ir), rhodium (Rh), molybdenum (Mo), or nickel (Ni) all have shorter mean free path lengths than copper and, accordingly, exhibit less electron scattering in response to imperfections at nanoscale. As a result, in modern chip designs, these and similar alternative metals may be favored over copper due to their better performance in real fabricated circuits (despite the better performance of copper in as-designed circuits).

### SUMMARY

Principles of the invention provide techniques for a top via structure made with a bi-layer template. In one aspect, an exemplary semiconductor structure, according to an aspect of the invention, includes a substrate defining a first trench; a first refractory metal liner coating the first trench; a heavy metal liner coating the first refractory metal liner; a copper structure filling the heavy metal liner; a generally planar capping dielectric layer on top of the substrate and the copper structure; a low-k dielectric layer on top of the capping dielectric layer; and a titanium nitride (TiN) layer on top of the low-k dielectric layer.

According to another aspect, an exemplary semiconductor structure includes a substrate defining a first trench; a first refractory metal liner coating the first trench; a heavy metal liner coating the first refractory metal liner; a copper structure filling the first trench over the heavy metal liner; a generally planar capping dielectric layer on top of the substrate and the copper structure; a low-k dielectric layer on top of the capping dielectric layer, wherein the low-k dielectric layer defines a second trench; a second refractory metal liner coating the second trench; a metal line filling the second refractory metal liner; and a metal via protruding from the metal line.

Another aspect provides an exemplary method for fabricating a semiconductor structure. The method includes obtaining a precursor structure. The precursor structure includes a substrate; a refractory metal liner coating a trench in the substrate; a heavy metal liner coating the refractory metal liner; and a copper structure filling the heavy metal liner. The precursor structure also includes a generally planar capping dielectric layer on top of the substrate and the copper structure; a low-k dielectric layer on top of the capping dielectric layer; a titanium nitride (TiN) layer on top of the low-k dielectric layer; and an etch stop layer between the low-k dielectric layer and the TiN layer. The method also includes depositing a hard mask and photoresist on the precursor structure; patterning a trench template in the photoresist and hard mask; etching a trench from the trench template through the TiN layer and the low-k dielectric layer to the copper structure; and depositing a liner in the trench and then filling the liner with an alternative filler metal.

In view of the foregoing, techniques of the present invention can provide substantial beneficial technical effects. For example, one or more embodiments provide one or more of:

Integrated circuit using alternative metal without significant line wiggling.

Integrated circuit with reduced damage to low-k dielectric from forming metal structures.

Integrated circuit with improved (reduced) variability of metal line and via dimensions.

Some embodiments may not have these potential advantages and these potential advantages are not necessarily required of all embodiments. These and other features and advantages of the present invention will become apparent from the following detailed description of illustrative embodiments thereof, which is to be read in connection with the accompanying drawings.

### BRIEF DESCRIPTION OF THE DRAWINGS

FIG. 1 depicts a top-down photomicrograph of a structure with metal deposited onto a low-k template.

FIG. 2 depicts a sectional view of the structure shown in FIG. 1, as seen from cut line 2-2.

FIG. 3 depicts a top-down photomicrograph of a titanium nitride (TiN) template.

FIG. 4 depicts a sectional view of the template shown in FIG. 3, as seen from cut line 4-4.

FIG. 5 depicts in a schematic a bi-layer TiN/low-k template, according to an exemplary embodiment.

FIG. 6 depicts a top-down photomicrograph of a bi-layer TiN/low-k template, according to an exemplary embodiment.

FIG. 7 depicts a sectional view of the bi-layer template of FIG. 7, as seen from cut line 7-7, according to an exemplary embodiment.

FIG. 8 depicts in a schematic a semiconductor structure fabricated on the template of FIG. 5, according to an exemplary embodiment.

FIG. 9 depicts in a flowchart steps of a process for fabricating the semiconductor structure of FIG. 8 on the bi-layer template of FIG. 5, according to an exemplary embodiment.

FIG. 10 depicts in a schematic a first intermediate structure formed on the bi-layer template of FIG. 5, according to an exemplary embodiment.

FIG. 11 depicts in a schematic a second intermediate structure formed on the bi-layer template of FIG. 5, according to an exemplary embodiment.

FIG. 12 depicts in a schematic a third intermediate structure formed on the bi-layer template of FIG. 5, according to an exemplary embodiment.

FIG. 13 depicts in a schematic a fourth intermediate structure formed on the bi-layer template of FIG. 5, according to an exemplary embodiment.

FIG. 14 depicts in a schematic a fifth intermediate structure formed on the bi-layer template of FIG. 5, according to an exemplary embodiment.

FIG. 15 depicts in a schematic a sixth intermediate structure formed on the bi-layer template of FIG. 5, according to an exemplary embodiment.

FIG. 16 depicts in a schematic a perspective view of the sixth intermediate structure.

FIG. 17 depicts in a schematic a seventh intermediate structure formed on the bi-layer template of FIG. 5, according to an exemplary embodiment.

FIG. 18 depicts in a schematic an eighth intermediate structure formed on the bi-layer template of FIG. 5, according to an exemplary embodiment.

FIG. 19 depicts in a schematic a ninth intermediate structure formed on the bi-layer template of FIG. 5, according to an exemplary embodiment.

FIG. 20 depicts in a schematic a perspective view of the ninth intermediate structure.

FIG. 21 depicts in a schematic a tenth intermediate structure formed on the bi-layer template of FIG. 5, according to an exemplary embodiment.

FIG. 22 depicts in a schematic an eleventh intermediate structure formed on the bi-layer template of FIG. 5, according to an exemplary embodiment.

FIG. 23 depicts in a schematic a twelfth intermediate structure formed on the bi-layer template of FIG. 5, according to an exemplary embodiment.

### DETAILED DESCRIPTION

In damascene-based back-end-of-line (BEOL) interconnects, the dielectric that separates the metal lines becomes mechanically weaker as the spacing between the metal lines is reduced. This weak dielectric is susceptible to wiggling/flopping over during the metallization process, particularly when alternative metals (generally having higher elastic moduli and thermal coefficients of expansion, compared to copper) are used as discussed above. We have discovered that using a high modulus template is very effective to alleviate this line wiggling issue. We consider titanium nitride (TiN) to be a good template because of its high modulus. However, replacing a TiN template with low-k dielectric, after metallization, is very challenging. In case TiN residues remain after replacing with low-k, line-to-line leakage is a significant concern.

Accordingly, we have found that it is desirable to provide a semiconductor fabrication process that combines the benefits of low-k dielectric and TiN modulus. By providing bi-layer TiN/low-k templates and associated processes, embodiments of the present invention mitigate line wiggling, reduce variability of metal dimensions in a finished product, and mitigate damage formerly caused to the low-k dielectric during etching for trenches to form metal structures.

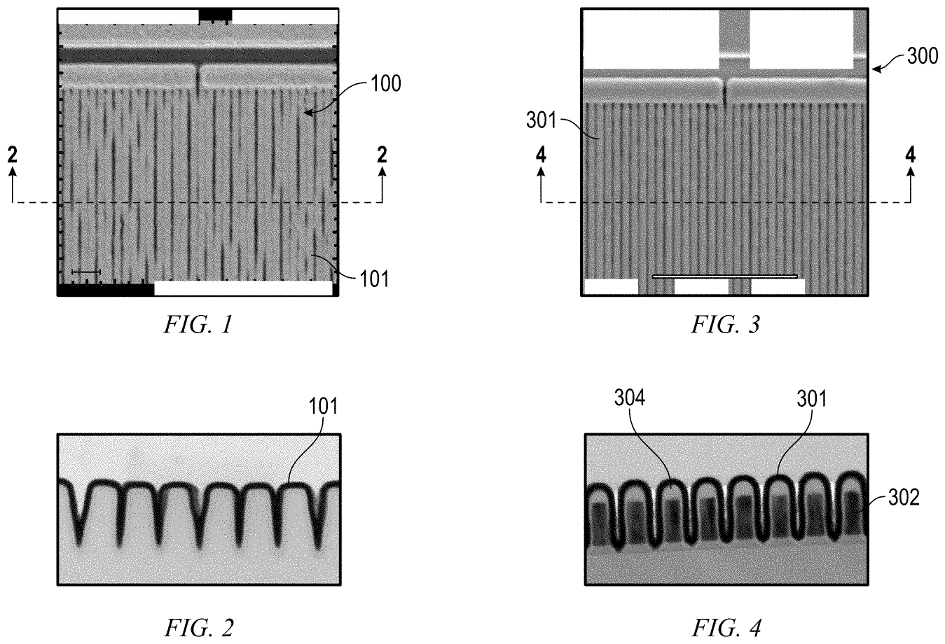

Referring to FIG. 1 and FIG. 2, thermal stresses from deposition of alternative metals cause line wiggling when using a low-k template 100. Because alternative metals normally have higher film stress than Cu, line wiggling tends to occur more frequently and severely during alternative metal deposition compared to Cu deposition. “Line wiggling” is a phenomenon of distortion in protruding structures of the template, which appears in FIG. 1 as waviness of lines 101 from a top-down view and appears in FIG. 2 as the lines 101 being tilted or bent toward each other.

Referring to FIG. 3 and FIG. 4, a template 300 containing TiN 302 and a hard mask 304 can mitigate line wiggling issue due to the high elastic modulus of the TiN (i.e., on the order of 100-1000 gigapascals (GPa)), which resists the thermal stresses from alternative metal deposition. The lines 301 and protruding structures in FIG. 3 and FIG. 4 exhibit uniformity and straightness not seen in FIG. 1 and FIG. 2.

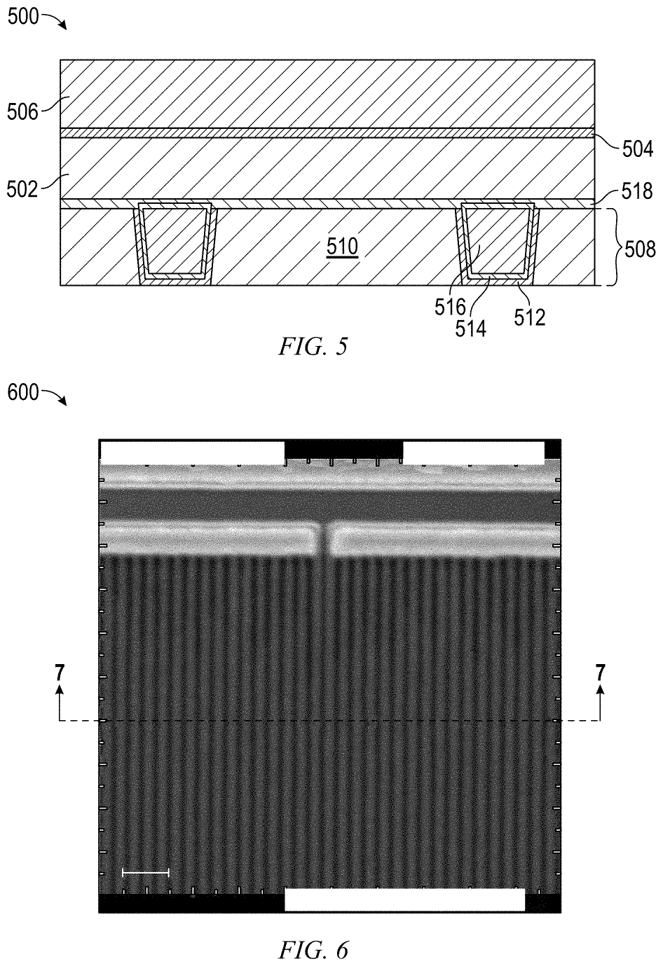

FIG. 5 depicts in a schematic a bi-layer TiN/low-k template 500, according to an exemplary embodiment. The bi-layer template 500 includes a low-k layer 502, an optional etch stop layer (ESL) 504, and a titanium nitride (TiN) layer 506. In one or more embodiments, the bi-layer template 502 is formed atop an optional underlying structure 508 that includes a substrate 510, a refractory metal (e.g., tantalum (Ta) or TaN) liner 512, a cobalt (Co) or similar heavy metal liner 514, copper structures 516, and a capping dielectric layer 518.

FIG. 6 depicts a top-down photomicrograph of a bi-layer TiN/low-k template 600, according to an exemplary embodiment.

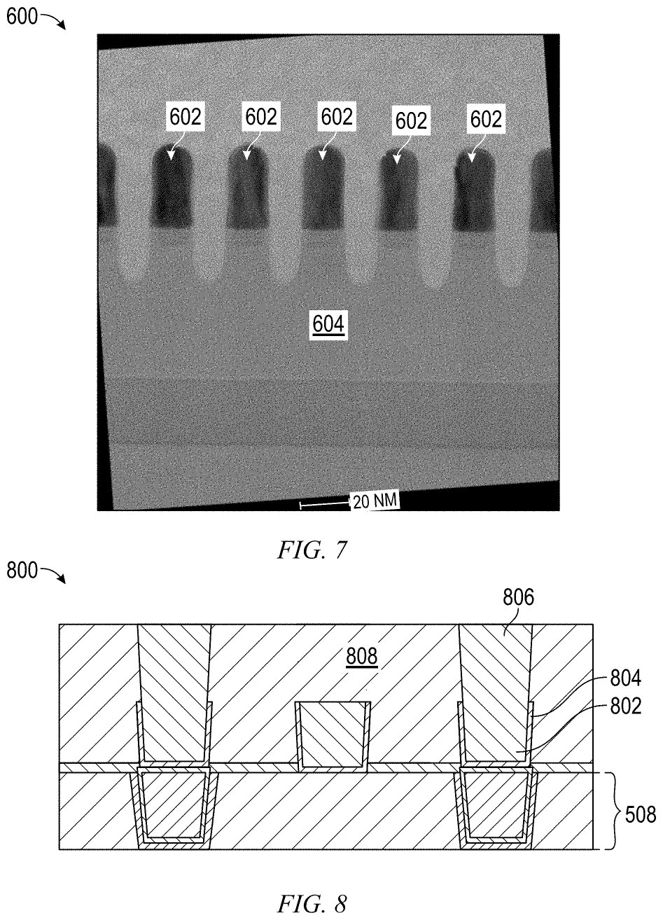

FIG. 7 depicts a sectional view of the bi-layer template 600 of FIG. 7, as seen from cut line 7-7, according to an exemplary embodiment. TiN 602 and low-k material 604 are easily distinguished in the grayscale photomicrograph.

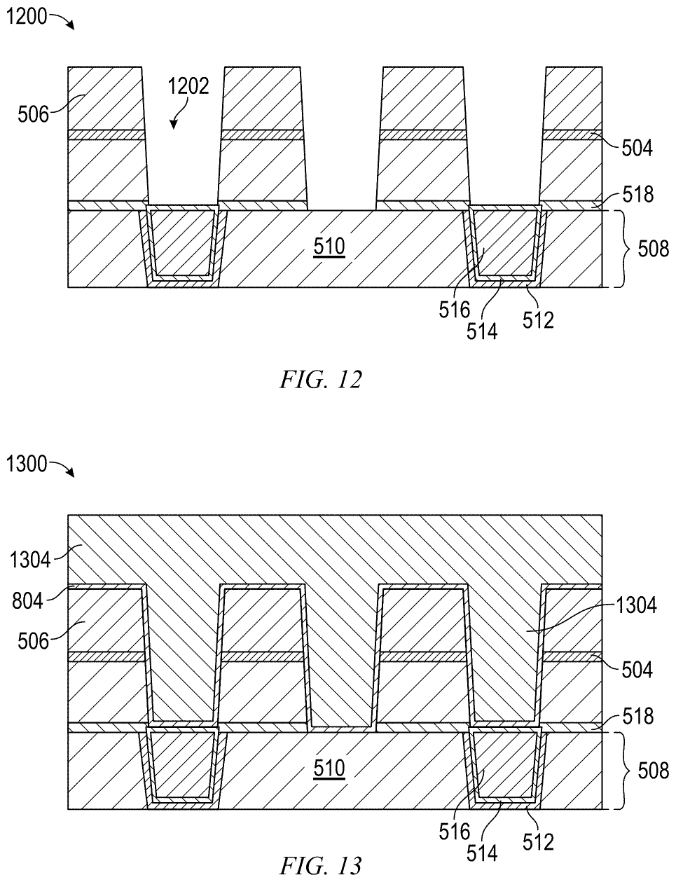

FIG. 8 depicts in a schematic a semiconductor structure 800 that is fabricated on the template of FIG. 5, according to an exemplary embodiment. The semiconductor structure 800 includes the optional underlying structure 508 as well as alternative metal lines 802, Ta or TaN liners 804, alternative metal vias 806, and low-k dielectric 808 encasing the lines and vias. Note there is no barrier or liner between the vias 806 and the dielectric 808. Additionally, for reasons further discussed below with reference to FIG. 12 and FIG. 23, the low-k dielectric 808 advantageously does not have the damage that typically arises from etching via trenches after dielectric deposition, according to conventional processes.

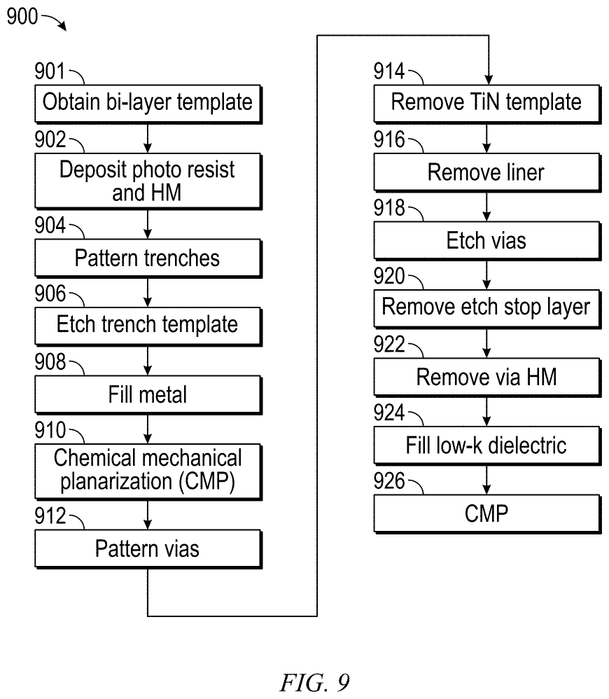

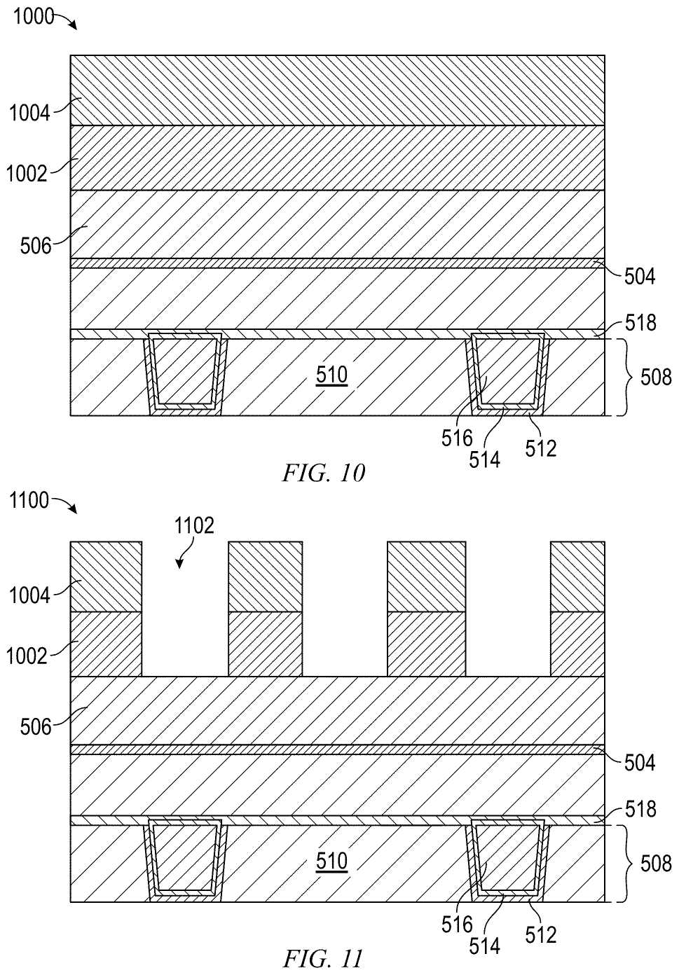

FIG. 9 depicts in a flowchart steps of a process 900 for fabricating the semiconductor structure 800 of FIG. 8 on the bi-layer template 500 of FIG. 5, according to an exemplary embodiment. At 901, obtain the bi-layer template 500. At 902, produce a first intermediate structure 1000 (as shown in FIG. 10) by depositing a hard mask 1002 and photoresist 1004; suitable materials for these (e.g., an allyl monomer or azide quinone for the photoresist; tetraethylorthosilicate (TEOS) for the hard mask) will be understood by the ordinary skilled worker. At 904, produce a second intermediate structure 1100 (as shown in FIG. 11) by patterning a trench template 1102 in the resist and hard mask. At 906, produce a third intermediate structure 1200 (as shown in FIG. 12) by etching the trench template through the TiN layer 506, the etch stop layer (ESL) 504, and the low-k dielectric 502 to form a trench 1202. As will be further discussed below with reference to FIG. 23, forming the trench 1202 at this step of the process reduces damage to the low-k dielectric 502 (relative to conventional process) and, in one or more embodiments, entirely eliminates damage to the low-k dielectric 808. At 908, produce a fourth intermediate structure 1300 (as shown in FIG. 13) by depositing a liner 804 (e.g., tantalum (Ta) or tantalum nitride (TaN)) and then filling alternative metal 1304 (e.g., rubidium (Ru), cobalt (Co), vanadium (Va), iridium (Ir), rhodium (Rh), molybdenum (Mo) or nickel (Ni)).

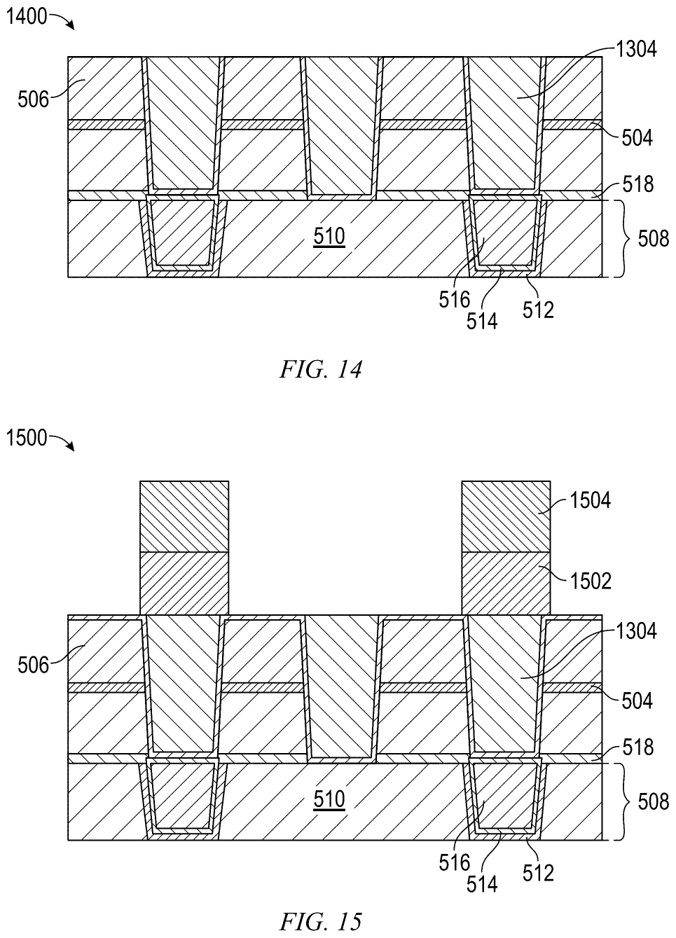

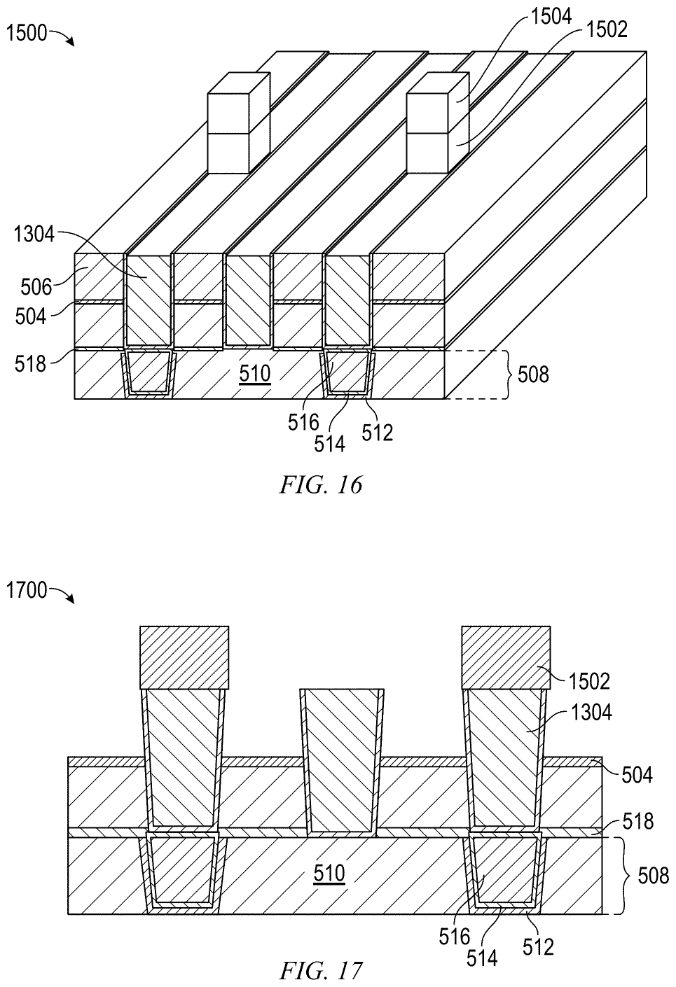

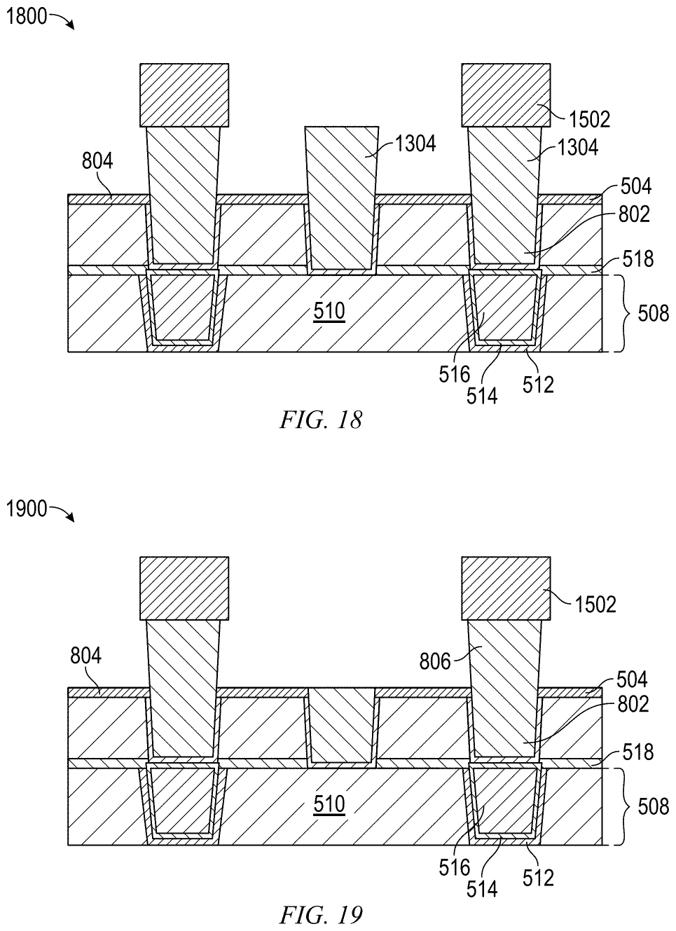

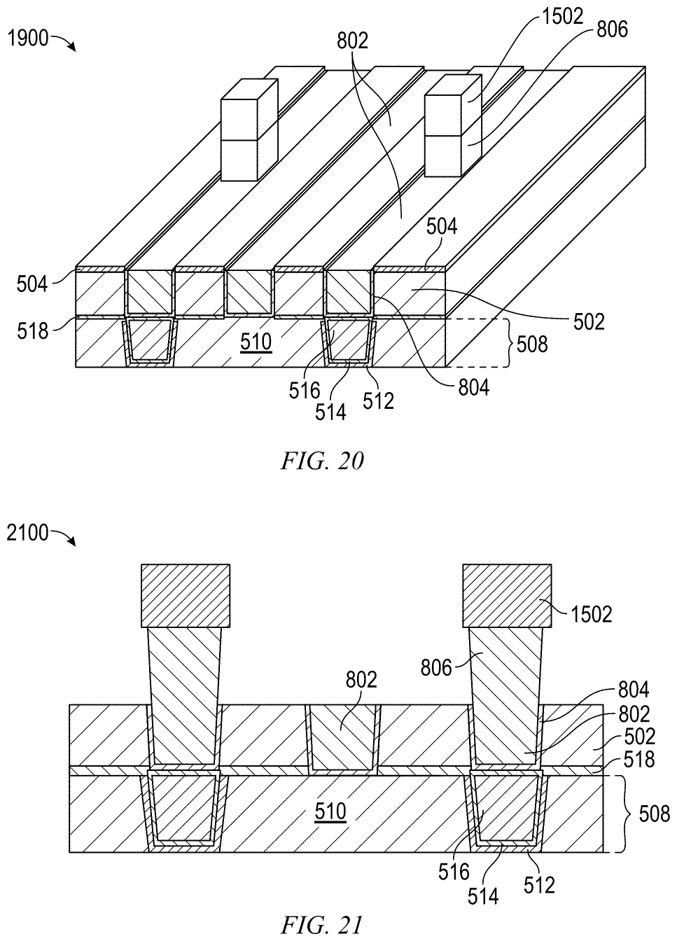

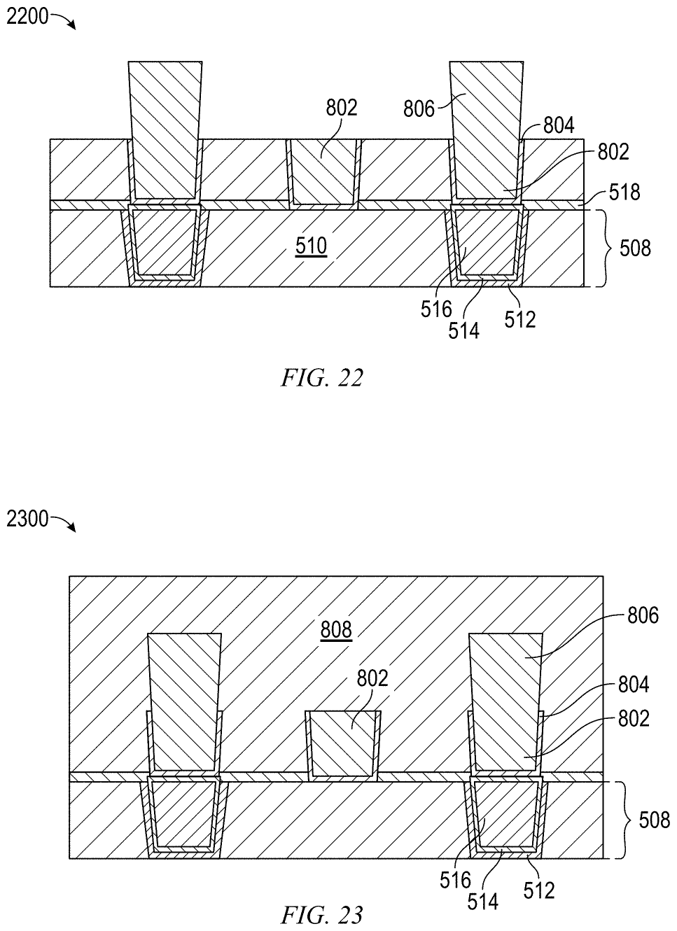

At 910, produce a fifth intermediate structure 1400 (as shown in FIG. 14) by chemical mechanical planarization (CMP) (also known as chemical mechanical polishing) of the fourth intermediate structure 1300. At 912, produce a sixth intermediate structure 1500 (as shown in FIG. 15 and FIG. 16) by patterning vias with a hard mask 1502 and photoresist 1504. At 914, produce a seventh intermediate structure 1700 (as shown in FIG. 17) by removing the TiN layer 506 (suitable chemistries for this step will be understood by the ordinary skilled worker, keeping in mind that in one or more embodiments the etch stop layer 504 is preserved at this step). At 916, produce an eighth intermediate structure 1800 (as shown in FIG. 18) by removing the portions of the liner 804 above the etch stop layer 504. At 918, produce a ninth intermediate structure 1900 (as shown in FIG. 19 and FIG. 20) by etching the filler metal 1304 to form vias 806 and lines 802. At 920, produce a tenth intermediate structure 2100 (as shown in FIG. 21) by removing the etch stop layer 504. At 922, produce an eleventh intermediate structure 2200 (as shown in FIG. 22) by removing the via etch hard mask 1502. At 924, produce a twelfth intermediate structure 2300 (as shown in FIG. 23) by filling with low-k dielectric 808 around the vias 806. Because the low-k dielectric 808 is filled after etching the trenches and filling the metal for lines and vias, the low-k dielectric 808 advantageously has no etch damage. Additionally, the low-k dielectric 808 advantageously contacts bare sides of the vias 806, without any intervening liner. Furthermore, not filling the low-k dielectric 808 until after etching of the filled metal to form vias and lines, means there is high selectivity of metal etch due to exposure of the metal on all sides. The high selectivity advantageously enables via height to be controlled by thickness of the TiN layer 506 and line height to be determined by thickness of the low-k layer 502. At 926, produce the semiconductor structure 800 (as shown in FIG. 8) by chemical mechanical planarization (CMP) of the twelfth intermediate structure 2300.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (ME), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, it will be appreciated that, in general terms, an exemplary semiconductor structure 500, according to an aspect of the invention, includes a substrate 510 defining a first trench; a first refractory metal liner 512 coating the first trench; a heavy metal liner 514 coating the first refractory metal liner; a copper structure 516 filling the heavy metal liner; a generally planar capping dielectric layer 518 on top of the substrate and the copper structure; a low-k dielectric layer 502 on top of the capping dielectric layer; and a titanium nitride (TiN) layer 506 on top of the low-k dielectric layer.

In one or more embodiments, the semiconductor structure 500 also includes an etch stop layer 504 between the low-k dielectric layer and the TiN layer.

In one or more embodiments, the semiconductor structure 500 also includes a hard mask 1002 on the TiN layer; and a photoresist 1004 on the hard mask. In one or more embodiments, the photoresist and the hard mask define a trench template 1102. In one or more embodiments, a trench 1202 extends from the trench template through the TiN layer, the low-k dielectric layer, and the capping dielectric layer to the copper structure.

In one or more embodiments, the semiconductor structure 500 also includes alternative metal 1304 filling the trench.

In one or more embodiments, the semiconductor structure 500 also includes a hard mask 1502 formed atop the alternative metal; and photoresist 1504 deposited atop the hard mask.

According to another aspect, an exemplary semiconductor structure 800 includes a substrate 510 defining a first trench; a first refractory metal liner 512 coating the first trench; a heavy metal liner 514 coating the first refractory metal liner; a copper structure 516 filling the first trench over the heavy metal liner; a generally planar capping dielectric layer 518 on top of the substrate and the copper structure; a low-k dielectric layer 502 on top of the capping dielectric layer, wherein the low-k dielectric layer defines a second trench; a second refractory metal liner 804 coating the second trench; a metal line 802 filling the second refractory metal liner; and a metal via 806 protruding from the metal line.

In one or more embodiments, the semiconductor structure 800 also includes a hard mask 1502 atop the metal via.

In one or more embodiments, the semiconductor structure 800 also includes an etch stop layer 504 atop the low-k dielectric layer.

In one or more embodiments, the refractory metal liner coats the metal via.

Another aspect provides an exemplary method 900 for fabricating a semiconductor structure. The method 900 includes, at 901, obtaining a precursor structure 500. The precursor structure 500 includes a substrate 510; a refractory metal liner 512 coating a trench in the substrate; 514 a heavy metal liner coating the refractory metal liner; and a copper structure 516 filling the heavy metal liner. The precursor structure 500 also includes a generally planar capping dielectric layer 518 on top of the substrate and the copper structure; a low-k dielectric layer 502 on top of the capping dielectric layer; a titanium nitride (TiN) layer 506 on top of the low-k dielectric layer; and an etch stop layer 504 between the low-k dielectric layer and the TiN layer. The method 900 also includes, at 902, depositing a hard mask and photoresist on the precursor structure; at 904, patterning a trench template in the photoresist and hard mask; at 906, etching a trench from the trench template through the TiN layer and the low-k dielectric layer to the copper structure; and, at 908, depositing a liner in the trench and then filling the liner with an alternative filler metal.

In one or more embodiments, the method 900 also includes, at 910 performing chemical mechanical planarization.

In one or more embodiments, the method 900 also includes, at 912 patterning vias with a hard mask and a photoresist.

In one or more embodiments, the method 900 also includes, at 914 removing the TiN layer.

In one or more embodiments, the method 900 also includes, at 916 removing portions of the liner above the etch stop layer.

In one or more embodiments, the method 900 also includes, at 918 etching the filler metal to form vias and lines.

In one or more embodiments, the method 900 also includes, at 920 removing the etch stop layer; and at 922 removing the via etch hard mask.

In one or more embodiments, the method 900 also includes, at 924 filling with low-k dielectric around the vias, wherein the low-k dielectric contacts sides of the vias.

In one or more embodiments, the method 900 also includes, at 926 producing a finished semiconductor structure by chemical mechanical polishing.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure comprising:
a substrate defining a first trench;
a first refractory metal liner coating the first trench;
a heavy metal liner coating the first refractory metal liner;
a copper structure filling the first trench over the heavy metal liner;
a generally planar capping dielectric layer on top of the substrate and the copper structure;
a low-k dielectric layer on top of the capping dielectric layer; and
a titanium nitride (TiN) layer on top of the low-k dielectric layer.

2. The semiconductor structure of claim 1, further comprising:
an etch stop layer between the low-k dielectric layer and the TiN layer.

3. The semiconductor structure of claim 1, further comprising:
a hard mask on the TiN layer; and
a photoresist on the hard mask.

4. The semiconductor structure of claim 3, wherein the photoresist and the hard mask define a trench template.

5. The semiconductor structure of claim 4, wherein a trench extends from the trench template through the TiN layer, the low-k dielectric layer, and the capping dielectric layer to the copper structure.

6. The semiconductor structure of claim 5, further comprising:
alternative metal filling the trench.

7. The semiconductor structure of claim 6, further comprising:
a hard mask located atop the alternative metal; and
photoresist located atop the hard mask.

8. A semiconductor structure comprising:
a substrate defining a first trench;
a first refractory metal liner coating the first trench;
a heavy metal liner coating the first refractory metal liner;
a copper structure filling the heavy metal liner;
a generally planar capping dielectric layer on top of the substrate and the copper structure;
a low-k dielectric layer on top of the capping dielectric layer, wherein the low-k dielectric layer defines a second trench;
a second refractory metal liner coating the second trench;
a metal line filling the second refractory metal liner; and
a metal via protruding from the metal line.

9. The semiconductor structure of claim 8, further comprising:
a hard mask atop the metal via.

10. The semiconductor structure of claim 8, further comprising:
an etch stop layer atop the low-k dielectric layer.

11. The semiconductor structure of claim 8, wherein the refractory metal liner coats the metal via.

12. A method for fabricating a semiconductor structure, the method comprising:
obtaining a precursor structure that comprises:
a substrate;
a refractory metal liner coating a trench in the substrate;
a heavy metal liner coating the refractory metal liner;
a copper structure filling the heavy metal liner;
a generally planar capping dielectric layer on top of the substrate and the copper structure;
a low-k dielectric layer on top of the capping dielectric layer;
a titanium nitride (TiN) layer on top of the low-k dielectric layer; and
an etch stop layer between the low-k dielectric layer and the TiN layer;
depositing a hard mask and photoresist on the precursor structure;
patterning a trench template in the photoresist and hard mask;
etching a trench from the trench template through the TiN layer and the low-k dielectric layer to the copper structure; and
depositing a liner in the trench and then filling the liner with an alternative filler metal.

13. The method of claim 12, further comprising:
performing chemical mechanical planarization.

14. The method of claim 13, further comprising:
patterning vias with a hard mask and a photoresist.

15. The method of claim 14, further comprising
removing the TiN layer.

16. The method of claim 15, further comprising:
removing portions of the liner above the etch stop layer.

17. The method of claim 16, further comprising:
etching the filler metal to form vias and lines.

18. The method of claim 17, further comprising:
removing the etch stop layer; and
removing the via etch hard mask.

19. The method of claim 18, further comprising:
filling with low-k dielectric around the vias, wherein the low-k dielectric contacts sides of the vias.

20. The method of claim 19, further comprising:
producing a finished semiconductor structure by chemical mechanical polishing.
